(19) United States
(12) Patent Application Publication
(10) Pub. No.: US 2021/0001739 A1
(43) Pub. Date: Jan. 7, 2021

(54) CHARGE/DISCHARGE DEVICE

(71) Applicant: Mitsubishi Electric Corporation, Tokyo (JP)

(72) Inventors: Hideyuki MURAI, Tokyo (JP); Tomomi MATSUI, Tokyo (JP); Hiroshi MURAI, Tokyo (JP)

(73) Assignee: Mitsubishi Electric Corporation, Tokyo (JP)

(21) Appl. No.: 16/622,344

(22) PCT Filed: Feb. 22, 2019
(86) PCT No.: PCT/JP2019/006887

§ 371 Date: Dec. 13, 2019

(51) Int. Cl. B60L 53/302; H02J 7/00

(52) U.S. Cl. CPC B60L 53/302; H02J 7/00309

(57) ABSTRACT

A charge/discharge device includes: a first component to be used for power conversion; a second component to be used for power conversion, the second component generating a smaller amount of heat than the first component during operation, the second component having a lower allowable temperature than the first component; a housing to house the first component and the second component; and an internal circulation fan to circulate air inside the housing. The first component is placed below the second component. The internal circulation fan is placed above the first component and blows air to the first component.

### FIELD

The present invention relates to a charge/discharge device capable of charging/discharging a drive storage battery.

### BACKGROUND

In recent years, electric cars such as electric vehicles (EVs) and plug-in hybrid electric vehicles (PHEVs) are becoming popular. With the spread of electric cars, household charge devices for home use that are charged with power supplied from a commercial system or power generated by a solar panel are becoming widespread. In addition, Vehicle to Home (V2H) systems represented by vehicle charge/discharge devices are also becoming widespread. A vehicle charge/discharge device can charge an electric car drive storage battery with power supplied from a commercial system or power generated by a solar panel, and can discharge and supply power from the electric car drive storage battery to a household electric instrument that is a domestic load.

Electronic components such as reactors and switching elements that are used for power conversion in a charge/discharge device generate heat when energized. In a charge/discharge device, electronic components such as relays and capacitors that generate a smaller amount of heat than reactors and switching elements and generate little heat when energized are also used for power conversion.

A typical charge/discharge device includes a cooling mechanism so that electronic components are not damaged due to a temperature increase. By lowering the ambient temperature in the housing of the charge/discharge device, the increase of the temperature of the electronic components in the housing is suppressed, and the lives of the electronic components can be ensured, so that the product life of the charge/discharge device can be ensured.

Components for power conversion are protected from water and dust by being housed inside the housing. In particular, a charge/discharge device for electric vehicles, which is used outdoors, is sealed so that rain or the like does not enter the housing. For this reason, the problem of the temperature of components is more remarkable in the charge/discharge device for electric vehicles.

As a device that performs power conversion, Patent Literature 1 discloses an inverter device in which an anti-convective plate is provided between an insulating transformer that is a heat-generating component and an electrolytic capacitor that generates little heat so as to suppress the increase of the ambient temperature of heat-sensitive components such as the electrolytic capacitor.

### CITATION LIST

### Patent Literature

Patent Literature 1: Japanese Patent Application Laid-open No. 2008-92632

### SUMMARY

### Technical Problem

However, in the inverter device described in Patent Literature 1, the temperature of the air in the housing is increased due to the generation of heat by a reactor. Hot air rises in the housing and accumulates in the upper region, which causes the ambient temperature of the upper region in the housing to increase and causes the ambient temperature of the lower region in the housing to decrease. For this reason, heat-sensitive components such as relays and capacitors must be placed in the lower region in the housing so that their lives are not shortened. Therefore, the inverter device of Patent Literature 1 is problematic because of the restriction on the arrangement of components in the housing.

The present invention has been made in view of the above, and an object thereof is to obtain a charge/discharge device having a high degree of freedom in the arrangement of components inside the housing.

### Solution to Problem

In order to solve the above-described problems and achieve the object, a charge/discharge device according to an aspect of the present invention includes: a first component to be used for power conversion; a second component to be used for power conversion, the second component generating a smaller amount of heat than the first component during operation, the second component having a lower allowable temperature than the first component; a housing to house the first component and the second component; and an internal circulation fan to circulate air inside the housing. The first component is placed below the second component. The internal circulation fan is placed above the first component and blows air to the first component.

### Advantageous Effects of Invention

The charge/discharge device according to the present invention can achieve the effect in that the degree of freedom in the arrangement of components inside the housing is large.

### BRIEF DESCRIPTION OF DRAWINGS

FIG. 1 is a diagram schematically illustrating a charge/discharge system including a charge/discharge device according to a first embodiment of the present invention.

FIG. 2 is a diagram illustrating an exemplary configuration of the charge/discharge system according to the first embodiment of the present invention.

FIG. 3 is a perspective view illustrating the external appearance of the charge/discharge device according to the first embodiment of the present invention as seen from the front.

FIG. 4 is a perspective view illustrating the external appearance of the charge/discharge device illustrated in FIG. 3 as seen from the back.

FIG. 5 is a perspective view of the charge/discharge device illustrated in FIG. 4 as seen through a duct and a system cable cover.

FIG. 6 is a schematic diagram illustrating substrates placed inside the charge/discharge device according to the first embodiment of the present invention.

FIG. 7 is a diagram illustrating the analysis result of a thermal fluid analysis for estimating the temperature distribution inside the housing or the charge/discharge device illustrated in FIG. 3.

FIG. 8 is a diagram illustrating the analysis result of a thermal fluid analysis for estimating the temperature distribution inside the housing of the charge/discharge device illustrated in FIG. 3.

FIG. 9 is a front view illustrating the charge/discharge device illustrated in FIG. 3, in which a front cover is removed and all the substrates are omitted.

FIG. 10 is a cross-sectional view of the charge/discharge device illustrated in FIG. 3.

### DESCRIPTION OF EMBODIMENTS

Hereinafter, a charge/discharge device according to embodiments of the present invention will be described in detail based on the drawings. The present invention is not limited to the embodiments.

### First Embodiment

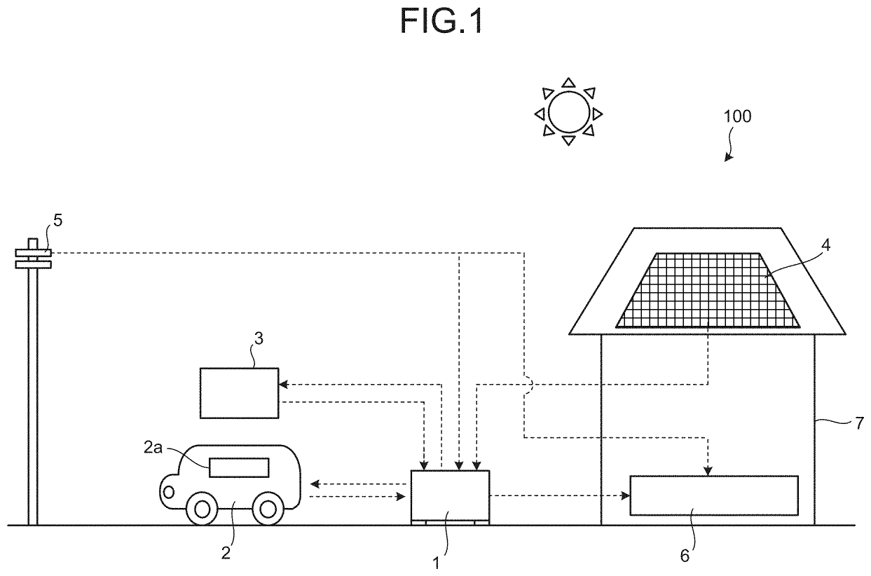

FIG. 1 is a diagram schematically illustrating a charge/discharge system 100 including a charge/discharge device 1 according to a first embodiment of the present invention. The charge/discharge system 100 includes the charge/discharge device 1, an electric car 2, an external storage battery 3, a solar panel 4, a system power source 5, and a load 6. The charge/discharge system 100 is a V2H system that charges a drive storage battery 2a mounted on the electric car 2 with power supplied from the solar panel 4 or the system power source 5, and discharges and supplies power stored in the drive storage battery 2a to the load 6.

The charge/discharge device 1 is a device that charges/discharges the drive storage battery 2a mounted on the electric car 2 or the external storage battery 3. The charge/discharge device 1 is electrically connected to the electric car 2, the external storage battery 3, the solar panel 4, the system power source 5, and the load. 6. Details of the charge/discharge device 1 will be described later.

Examples of the electric car 2 include an electric vehicle and a plug-in hybrid electric vehicle. Inside the electric car 2, the drive storage battery 2a is mounted to be used for driving the electric car 2. The drive storage battery 2a is a secondary battery capable of DC power charging and discharging. The drive storage battery 2a can store DC power, and also functions as a DC power source for discharging. The drive storage battery 2a is implemented by, for example, a nickel metal hydride battery or a lithium ion battery.

The external storage battery 3 is provided outside the electric car 2. The external storage battery 3 is a storage battery different from the drive storage battery 2a of the electric car 2. The external storage battery 3 is a secondary battery capable of DC power charging and discharging. The external storage battery 3 is, for example, a nickel metal hydride battery or a lithium ion battery. Note that the external storage battery 3 may be omitted in a V2H system.

The solar panel 4 is a power generator that is installed on the roof of a house 7 and converts sunlight into DC power. The solar panel 4 functions as a DC power source. The solar panel 4 is an example of a DC power source external to the charge/discharge device 1.

The system power source 5 is an AC power source that supplies AC power to the charge/discharge device 1 or the load 6.

The load 6 is an instrument that consumes power, e.g. an electric instrument installed in the house 7. Examples of the electric instrument include an air conditioner, a refrigerator, and a microwave oven. The load 6 electrically connected to the system power source 5 via the charge/discharge device 1, and also electrically connected to the system power source 5 without involving the charge/discharge device 1.

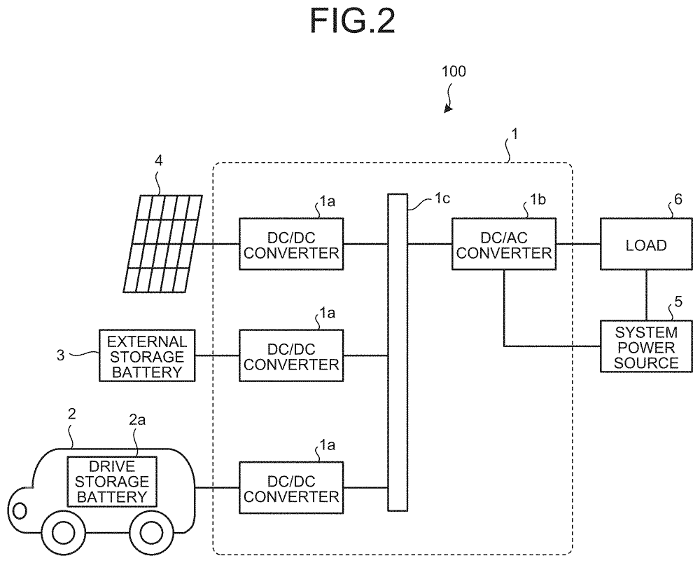

FIG. 2 is a diagram illustrating an exemplary configuration of the charge/discharge system 100 according to the first embodiment of the present invention. The charge/discharge device 1 includes a plurality of DC/DC converters 1a, a DC/AC converter 1b, and a connector 1c.

The DC/DC converters 1a are devices that convert a direct current into a direct current having a different voltage value. The DC/DC converters 1a are connected on a one-to-one basis to the electric car 2, the external storage battery 3, and the solar panel 4. In the example illustrated in FIG. 2, one solar panel 4 is installed. Alternatively, in a case where two or more solar panels 4 are installed, DC/DC converters 1a are connected on a one-to-one basis to the solar panels 4. Each of the DC/DC converters 1a is configured using components such as a DC reactor, a switching element, a diode, and a capacitor. When the DC/DC converter 1a converts a direct current into a direct current having a different voltage value, heat is generated especially in the DC reactor and the switching element.

The DC/AC converter 1b is a device that mutually converts a direct current and an alternating current. The DC/AC converter 1b is electrically connected to the system power source 5 and the load 6. The DC/AC converter 1b is configured using components such as an AC reactor, a switching element, a capacitor, and a relay. When the DC/AC converter 1b mutually converts a direct current and an alternating current, heat is generated especially in the AC reactor and the switching element.

The connector 1c is electrically connected to the drive storage battery 2a, the external storage battery 3, and the solar panel 4 via the DC/DC converter 1a, and electrically connected to the system power source 5 and the load 6 via the DC/AC converter 1b.

The charge/discharge system 100 can charge the drive storage battery 2a or the external storage battery 3 with power generated by the solar panel 4. Specifically, DC power generated by the solar panel 4 is supplied to the drive storage battery 2a or the external storage battery 3 through the DC/DC converter 1a, the connector 1c, and the DC/DC converter 1a of the charge/discharge device 1.

The charge/discharge system 100 can also charge the drive storage battery 2a or the external storage battery 3 with power supplied from the system power source 5. Specifically, AC power supplied from the system power source 5 is converted into DC power by the DC/AC converter 1b of the charge/discharge device 1, and is then supplied to the drive storage battery 2a or the external storage battery 3 through the connector 1c and the DC/DC converter 1a.

The charge/discharge system 100 can also discharge power stored in the drive storage battery 2a or the external storage battery 3 and supply the discharged power to the load 6. Specifically, DC power stored in the drive storage battery 2a or the external storage battery 3 is transmitted to the DC/AC converter 1b through the DC/DC converter 1a and the connector 1c of the charge/discharge device 1, converted into AC power by the DC/AC converter 1b, and supplied to the load 6. The charge/discharge system 100 can supply power stored in the drive storage battery 2a or the external storage battery 3 to the load 6 via the charge/discharge device 1, for example, when the amount of power generated by the solar panel 4 is insufficient due to bad weather, when the supply of power from the system power source 5 to the load 6 is stopped, or when the power generated by the solar panel 4 is lower than the power consumption of the load 6.

The charge/discharge system 100 can also supply power generated by the solar panel 4 to the load 6. Specifically, DC power generated by the solar panel 4 is transmitted through the DC/DC converter 1a, the connector 1c, and the DC/AC converter 1b of the charge/discharge device 1, converted into AC power by the DC/AC converter 1b, and supplied to the load. 6.

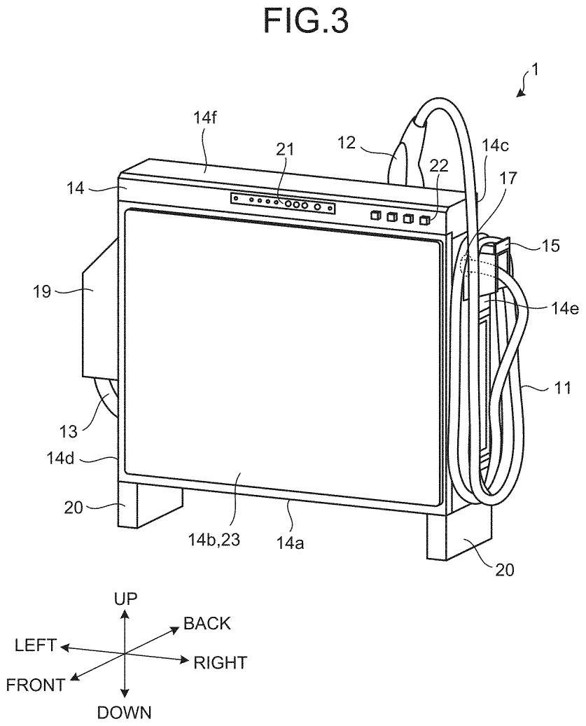

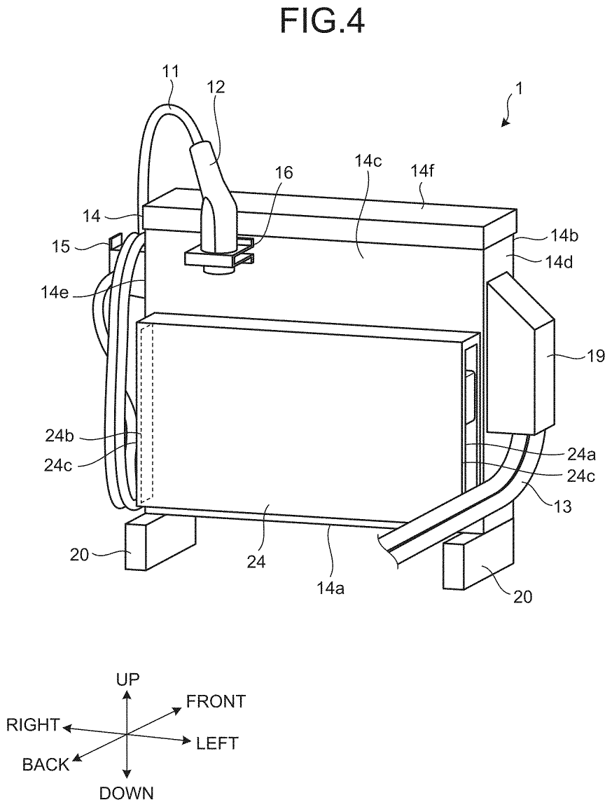

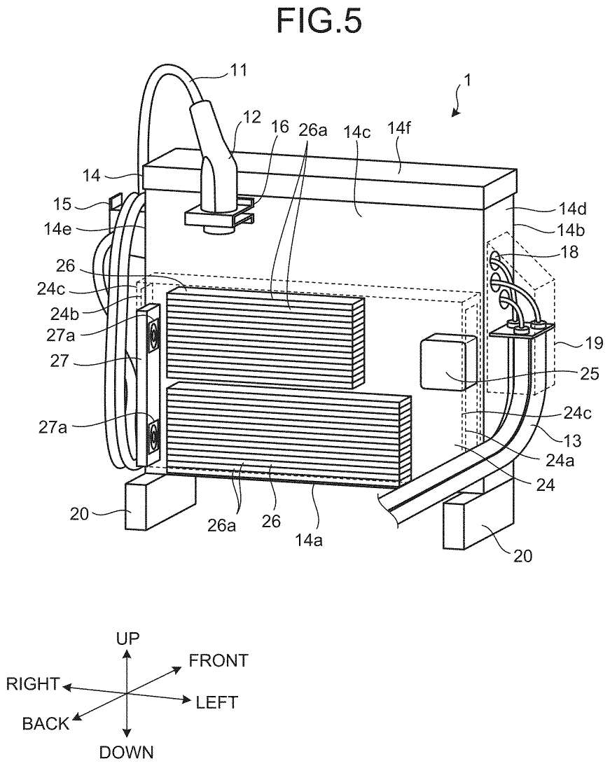

FIG. 3 is a perspective view illustrating the external appearance of the charge/discharge device 1 according to the first embodiment of the present invention as seen from the front. FIG. 4 is a perspective view illustrating the external appearance of the charge/discharge device 1 illustrated in FIG. 3 as seen from the back. FIG. 5 is a perspective view of the charge/discharge device 1 illustrated in FIG. 4 as seen through a duct 24 and a system cable cover 19.

The charge/discharge device 1 includes a charge/discharge cable 11, a charge/discharge connector 12, and a system cable 13. The charge/discharge cable 11 serves as a charge/discharge path for the electric car 2 or the external storage battery 3. The charge/discharge connector 12 is attached to the end of the charge/discharge cable 11 and electrically connected to the electric car 2 or the external storage battery 3. The system cable 13 is electrically connected to the system power source 5. The charge/discharge device 1 also includes a housing 14, a charge/discharge cable holder 15, and a charge/discharge connector holder 16. The housing 14 houses the charge/discharge cable 11 and the system cable 13. The charge/discharge cable holder 15 holds the charge/discharge cable 11 drawn out of the housing 14. The charge/discharge connector holder 16 holds the charge/discharge connector 12. The charge/discharge connector 12 is connected to the charging port of the electric car 2, for example.

The housing 14 is a metal member that constitutes the outline of the charge/discharge device 1, and has a box shape. The housing 14 includes a housing front surface 14b and a housing back surface 14c. The housing front surface 14b is a front surface that the user faces when performing a charge/discharge operation with the charge/discharge device 1. The housing back surface 14c is a back surface that faces away from the user with the housing front surface 14b interposed therebetween. The housing 14 also includes a housing left side surface 14d that is a left side surface and a housing right side surface 14e that is a right side surface. The housing 14 further includes a housing bottom surface 14a and a housing top surface 14f. The housing bottom surface 14a is a bottom surface that faces an installation surface that is the surface on which the charge/discharge device 1 is placed. The housing top surface 14f is a top surface. Note that the directions described in the first embodiment are based on the premise that the normal direction of the housing front surface 14b is the front, the normal direction of the housing back surface 14c is the back, and the vertical direction and the horizontal direction are directions viewed from the user facing the housing front surface 14b.

The housing bottom surface 14a is a rectangular horizontal plane. Legs 20 are provided at both horizontal ends of the housing bottom surface 14a and are in contact with the installation surface. The housing top surface 14f is a rectangular horizontal plane placed above the housing bottom surface 14a at a distance from the housing bottom surface 14a.

The housing from surface 14b is a rectangular vertical plane that connects the front ends of the housing bottom surface 14a and the housing top surface 14f. A display unit 21 for displaying ON/OFF of the charge/discharge device 1, a charging state, a discharging state, and the like is provided in the middle of the upper part of the housing front surface 14b. On the right side of the housing front surface 14b relative to the display unit 21, a switch unit 22 is provided for switching between ON and OFF of the charge/discharge device 1, between charging and discharging, and the like. The part of the housing front surface 14b below the display unit 21 and the switch unit 22 is configured by a separate front cover 23 formed in a flat plate shape.

The housing right side surface 14e is a rectangular vertical plane that connects the right ends of the housing bottom surface 14a and the housing top surface 14f. On the housing right side surface 14e, a charge/discharge cable outlet 17 is provided for drawing the charge/discharge cable 11 out of the housing 14. The charge/discharge cable holder 15 is provided on the housing right side surface 14e and covers the charge/discharge cable outlet 17. The middle part of the charge/discharge cable 11 drawn out of the housing 14 is wound multiple times into a ring shape and hung and held on the charge/discharge cable holder 15.

The housing left side surface 14d is a rectangular vertical plane that connects the left ends of the housing bottom surface 14a and the housing top surface 14f. On the housing left side surface 14d, a system cable outlet 18 is provided for drawing the system cable 13 out of the housing 14. The system cable cover 19 that covers part of the system cable 13 and the system cable outlet 18 is provided on the housing left side surface 14d.

The housing back surface 14c is a rectangular vertical plane that connects the back ends of the housing bottom surface 14a and the housing top surface 14f. The charge/discharge connector holder 16 is provided on the housing back surface 14c. The duct 24 that forms an air path together with the housing back surface 14c is placed on the housing back surface 14c. The duct 24 is formed in a box shape that opens forward. An intake port 24a and an exhaust port 24b of the duct 24 are formed on left and right duct side surfaces 24c of the duct 24 extending in a direction intersecting the housing back surface 14c. In the first embodiment, air flows from the left to the right of the duct 24.

As illustrated in FIG. 5, a cover 25, a heat sink 26, and a fan unit 27 are placed in the duct 24 in this order from the upstream side in the ventilation direction. The cover 25, the heat sink 26, and the fan unit 27 are attached to the housing back surface 14c.

The cover 25 is a metal member that is formed in a box shape that opens forward, and covers, from the back side, an electronic component placed inside the housing 14 and protruding backward. The cover 25 is placed at a position close to the intake port 24a.

The heat sink 26 is a metal member that radiates heat from switching elements 28 (described later). The heat sink 26 is made of a high thermal conductivity material such as copper or aluminum. The heat sink 26 has a rectangular parallelepiped shape. The number of heat sinks 26 is not limited to a specific number. In the first embodiment, two heat sinks 26 are spaced apart from each other in the vertical direction. The heat sink 26 has a plurality of fins 26a. The fins 26a are placed perpendicular to the housing back surface 14c and extends along the horizontal direction. The plurality of fins 26a of the heat sink 26 are placed at intervals in the vertical direction. That is, the fins 26a are placed in a manner that does not disturb the flow of air in the horizontal direction.

The fan unit 27 is an instrument that allows air to flow through the duct 24. The fan unit 27 is placed near the right duct side surface 24c of the duct 24. The fan unit 27 includes two fans 27a that are spaced apart from each other in the vertical direction. In the charge/discharge device 1 according to the first embodiment, heat transmitted from the switching elements 28 (described later) to the heat sinks 26 is radiated by forced air cooling using the fan unit 27 for forced air cooling. Note that the left and right positions of the intake port 24a and the exhaust port 24b may be reversed. Specifically, the fan unit 27 may be placed such that the opening formed in the right duct side surface 24c serves as the intake port 24a and the opening formed in the left duct side surface 24c serves as the exhaust port 24b. In this case, air flows from the right to the left of the duct 24.

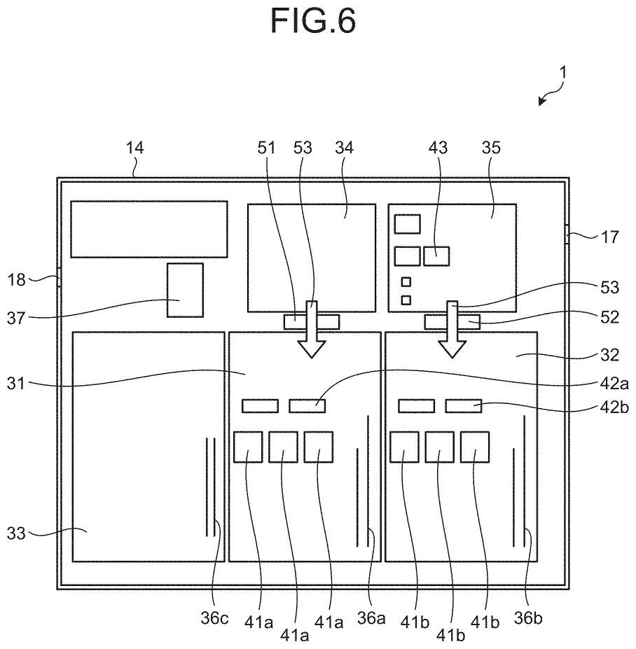

FIG. 6 is a schematic diagram illustrating substrates placed inside the charge/discharge device 1 according to the first embodiment of the present invention.

Inside the housing 14 of the charge/discharge device 1, a first substrate 31, a second substrate 32, a third substrate 33, a fourth substrate 34, and a filter substrate 35 are placed. The first substrate 31, the second substrate 32, and the third substrate 33 are placed in parallel on the same plane in the horizontal direction, with their in-plane directions parallel with each other. The fourth substrate 34 is placed above the first substrate 31. The filter substrate 35 is placed above the second. substrate 32.

On the first substrate 31, first reactors 41a that are reactors and a first capacitor 42a that is a capacitor are mounted. The first reactor 41a is a first component that is used for power conversion. The first capacitor 42a is a second component that is used for power conversion, generates a smaller amount of heat than the first component during operation, and has a lower allowable temperature than the first component. The first capacitor 42a is placed above the first reactors 41a. On the first substrate 31, a first standing substrate 36a is mounted and connected to the first substrate 31. The first standing substrate 36a rises forward from the surface of the first substrate 31. The first standing substrate 36a is placed perpendicular to the in-plane direction of the first substrate 31. The first standing substrate 36a is a substrate that is used for power conversion. Components that are used for power conversion are mounted on the first standing substrate 36a. The first substrate 31 and the first standing substrate 36a are substrates that constitute, for example, the DC/DC converter 1a.

On the second substrate 32, second reactors 41b that are reactors and a second capacitor 42b that is a capacitor are mounted. The second reactor 41b is a first component that is used for power conversion. The second capacitor 42b is a second component that is used for power conversion, generates a smaller amount of heat than the first component during operation, and has a lower allowable temperature than the first component. On the second substrate 32, a second standing substrate 36b is mounted and connected to the second substrate 32. The second standing substrate 36b rises forward from the surface of the second substrate 32. The second standing substrate 36b is placed perpendicular to the in-plane direction of the second substrate 32. The second standing substrate 36b is a substrate that is used for power conversion. Components that are used for power conversion are mounted on the second standing substrate 36b. The second substrate 32 and the second standing substrate 36b are substrates that constitute, for example, the DC/AC converter 1b.

Since the first reactors 41a are mounted on the first substrate 31 and the second reactors 41b are mounted on the second substrate 32 as described above, components for placing the first reactors 41a and the second reactors 41b in the housing 14 are unnecessary, and the cost can be reduced.

On the third substrate 33, a third standing substrate 36c is mounted and connected to the third substrate 33. The third standing substrate 36c rises forward from the surface of the third substrate 33. The third standing substrate 36c is placed perpendicular to the in-plane direction of the third substrate 33.

In the first embodiment, using a technique of substrate-to-substrate connection, the first standing substrate 36a is configured such that the in-plane direction of the first substrate 31 and the in-plane direction of the first standing substrate 36a are perpendicular to each other. Similarly, the second standing substrate 36b is configured using a technique of substrate-to-substrate connection such that the in-plane direction of the second substrate 32 and the in-plane direction of the second standing substrate 36b are perpendicular to each other. Similarly, the third standing substrate 36c is placed using a technique of substrate-to-substrate connection such that the in-plane direction of the third substrate 33 and the in-plane direction of the third standing substrate 36c are perpendicular to each other. The in-plane direction of the first standing substrate 36a, the in-plane direction of the second standing substrate 36b, and the in-plane direction of the third standing substrate 36c are parallel with each other.

A first internal circulation fan 51 that circulates the air inside the housing 14 is placed above the first substrate 31. The first internal circulation fan 51 is placed between the first substrate 31 and the fourth substrate 34 and immediately above the first substrate 31. A second internal circulation fan 52 that circulates the air inside the housing 14 is placed above the second substrate 32. The second internal circulation fan 52 is placed between the second substrate 32 and the filter substrate 35 and immediately above the second substrate 32. That is, in the first embodiment, internal circulation fans are individually placed on a one-to-one basis for the first substrate 31 and the second substrate 32, which are a plurality of substrates on which reactors are mounted.

In FIG. 6, the directions in which air is blown from the first internal circulation fan 51 and the second internal circulation fan 52 are indicated by arrows 53. That is, the first internal circulation fan 51 blows air downward in the housing 14 to the first reactors 41a. The second internal circulation fan 52 blows air downward in the housing 14 to the second reactors 41b.

The filter substrate 35 having a function of removing noise components included in the DC voltage input when the electric car 2 is charged/discharged is placed inside the housing 14 of the charge/discharge device 1. The filter substrate 35 is placed above the second internal circulation fan 52. That is, the filter substrate 35 is placed above the second substrate 32. Electronic components including a relay 43 are mounted on the filter substrate 35. The relay 43 is a second component that generates a smaller amount of heat than the first component during operation and has a lower allowable temperature than the first component. In addition to the relay 43, another electronic component that generates a smaller amount of heat than the first component during operation and has a lower allowable temperature than the first component is mounted on the filter substrate 35.

A terminal block 37 is placed above the third substrate 33. The terminal block 37 is connected to a wire that connects to the system cable 13 drawn into the housing 14 through the system cable outlet 18. The system cable outlet 18 and the charge/discharge cable outlet 17 are placed in higher positions than the first internal circulation fan 51 and the second internal circulation fan 52 so that a wire inside the housing 14 for connecting the system cable 13 and the charge/discharge cable 11 to the filter substrate 35 and the terminal block 37 is shortened.

In addition to the above-mentioned substrates, the housing 14 of the charge/discharge device 1 contains, for example, a substrate having a function of supplying power to each substrate housed in the housing 14 and controlling the power supply to each substrate when the electric car 2 is charged/discharged.

Next, the effects of the configuration of the charge/discharge device 1 will be described. In the first embodiment, the system cable outlet 18 is placed in an upper position on the housing left side surface 14d of the housing 14 so that the influence of dirt and dust from the installation surface of the charge/discharge device 1, the influence of rain bouncing off the installation surface in rainy weather, and the like are reduced. Similarly, the charge/discharge cable outlet 17 is placed in an upper position on the housing right side surface 14e of the housing 14 so that the influence of dirt and dust from the installation surface of the charge/discharge device 1, the influence of rain bouncing off the installation surface in rainy weather, and the like are reduced.

The system cable outlet 18 and the charge/discharge cable outlet 17 are placed in higher positions than the first internal circulation fan 51 and the second internal circulation fan 52 so that a wire inside the housing 14 for connecting the system cable 13 and the charge/discharge cable 11 to the filter substrate 35 and the terminal block 37 is shortened. By shortening the wire for power transmission, it is possible to reduce noise components included in the voltage for charging/discharging.

With such a configuration, the first substrate 31 on which the first reactors 41a are mounted and the second substrate 32 on which the second reactors 41b are mounted are placed across the vertical middle region and the lower region inside the housing 14. The first reactors 41a and the second reactors 41b are placed in the lower region inside the housing 14.

When the charge/discharge device 1 operates, e.g. converts a direct current into a direct current having a different voltage value, mutually converts a direct current and an alternating current, and the like, various components housed in the housing 14 generate heat. In particular, reactors are heat-resistant components that generate a large amount of heat during operation and have an allowable temperature of, for example, 120° C. or higher. That is, among the components housed in the housing 14, the first reactors 41a and the second reactors 41b are high heat-generating components that generate a relatively large amount of heat and become hot during operation and have high heat resistance.

When the charge/discharge device 1 operates, heat generated by the first reactors 41a and the second reactors 41b is radiated to the air inside the housing 14. The air becomes hot by being heated by the heat generated and radiated by the first reactors 41a and the second reactors 41b, rises in the housing 14, and accumulates in the upper region in the housing 14. Consequently, the ambient temperature of the upper region in the housing 14 increases.

In contrast, the relay 43 mounted on the filter substrate 35 is a heat-sensitive component having a lower allowable temperature than reactors, for example, 85° C. That is, among the components housed in the housing 14, the relay 43 is a low heat-resistant component that generates a relatively smaller amount of heat than high heat-generating components during operation and has a lower heatproof temperature than high heat-generating components. In the first embodiment, the filter substrate 35 is placed in the upper region inside the housing 14, and the relay 43 is accordingly placed in the upper region inside the housing 14. In this case, the ambient temperature of the upper region in the housing 14 increases due to the generation of heat by the first reactors 41a and the second reactors 41b, and the temperature of the relay 43 increases, which shortens the life of the relay 43.

Therefore, in the first embodiment, the first internal circulation fan 51 is placed between the first substrate 31 on which the first reactors 41a are mounted and the fourth substrate 34. Then, the first internal circulation fan 51 blows air downward in the housing 14 to the first reactors 41a. Consequently, in the charge/discharge device 1, the first reactors 41a are directly cooled, and hot air heated by the heat radiation from the first reactors 41a can be prevented from rising in the housing 14. As a result, the increase of the ambient temperature of the upper region in the housing 14 can be suppressed.

In the first embodiment, the second internal circulation fan 52 is placed between the second substrate 32 on which the second reactors 41b are mounted and the filter substrate 35 on which the relay 43 is mounted. Then, the second internal circulation fan 52 blows air downward in the housing 14 to the second reactors 41b. Consequently, in the charge/discharge device 1, the second reactors 41b are directly cooled, and hot air heated by the heat radiation from the second reactors 41b can be prevented from rising in the housing 14. As a result, the increase of the ambient temperature of the upper region in the housing 14 can be suppressed.

That is, in the charge/discharge device 1, among the components housed in the housing 14, exhaust heat from the components that generate a large amount of heat during operation is prevented from rising in the housing 14, and the air temperature difference in the vertical direction can be reduced inside the housing 14. Consequently, the increase of the ambient temperature of the upper region in the housing 14 due to the generation of heat by the first reactors 41a and the second reactors 41b is suppressed, and the life of the relay 43 placed in the upper region inside the housing 14 can be prevented from being shortened. The blowing direction of the first internal circulation fan 51 and the blowing direction of the second internal circulation fan 52 are the same.

As the increase of the ambient temperature of the upper region in the housing 14 is suppressed, it is possible to prevent the life of another electronic component on the filter substrate 35 which generates a smaller amount of heat than the first component during operation and has a lower allowable temperature than the first component similarly to the relay 43 from being shortened.

Air blown from the first internal circulation fan 51 also hits the first capacitor 42a, which is a component other than the first reactors 41a mounted on the first substrate 31. Consequently, the first capacitor 42a is directly cooled, so that its temperature can be lowered. Thus, the life of the first capacitor 42a can be extended.

Air blown from the second internal circulation fan 52 also hits the second capacitor 42b, which is a component other than the second reactors 41b mounted on the second substrate 32. Consequently, the second capacitor 42b is directly cooled, so that its temperature can be lowered. Thus, the life of the second capacitor 42b can be extended.

Further, on the first substrate 31, the first standing substrate 36a vertically rising forward from the surface of the first substrate 31 is placed. On the second substrate 32, the second standing substrate 36b vertically rising forward from the surface of the second substrate 32 is placed. On the third substrate 33, the third standing substrate 36c vertically rising forward from the surface of the third substrate 33 is placed.

The first standing substrate 36a is placed such that the in-plane direction is perpendicular to the first substrate 31 and the in-plane direction is parallel with the blowing direction of the first internal circulation fan 51. The first standing substrate 36a serving as a wall can prevent air blown from the first internal circulation fan 51 from spreading in the right direction from the first reactors 41a. Therefore, air blown from the first internal circulation fan 51 is efficiently blown to the first reactors 41a. Consequently, exhaust heat from the first reactors 41a can be further prevented from rising the housing 14.

The third standing substrate 36c placed such that the in-plane direct on is perpendicular to the third substrate 33 and the in-plane direction is parallel with the blowing direction of the first internal circulation fan 51. The third standing substrate 36c serving as a wall can prevent air blown from the first internal circulation fan 51 from spreading in the left direction from the first reactors 41a. Therefore, air blown from the first internal circulation fan 51 is efficiently blown to the first reactors 41a. Consequently, exhaust heat from the first reactors 41a can be further prevented from rising in the housing 14.

The second standing substrate 36b is placed such that the in-plane direction is perpendicular to the second substrate 32 and the in-plane direction is parallel with the blowing direction of the second internal circulation fan 52. The second standing substrate 36b serving as a wall can prevent air blown from the second internal circulation fan 52 from spreading in the right direction from the second reactors 41b. Therefore, air blown from the second internal circulation fan 52 is efficiently blown to the second reactors 41b. Consequently, exhaust heat from the second reactors 41b can be further prevented from rising in the housing 14.

The first stranding substrate 36a serving as a wall can prevent air blown from the second internal circulation fan 52 from spreading in the left direction from the second reactors 41b. Therefore, air blown from the second internal circulation fan 52 is efficiently blown to the second reactors 41b. Consequently, exhaust heat from the second reactors 41b can be further prevented from rising in the housing 14.

That is, the first standing substrate 36a, the second standing substrate 36b, and the third standing substrate 36c, whose in-plane directions are parallel with the blowing direction of the internal circulation fans, function as walls that limit the spread of air blown from the internal circulation fans to the first component. By using the substrates for power conversion as walls, it is not necessary to provide dedicated walls, and the cost can be reduced. In the first embodiment, substrates that function as walls may be provided between the first substrate 31 and the second substrate 32 and between the first substrate 31 and the third substrate 33.

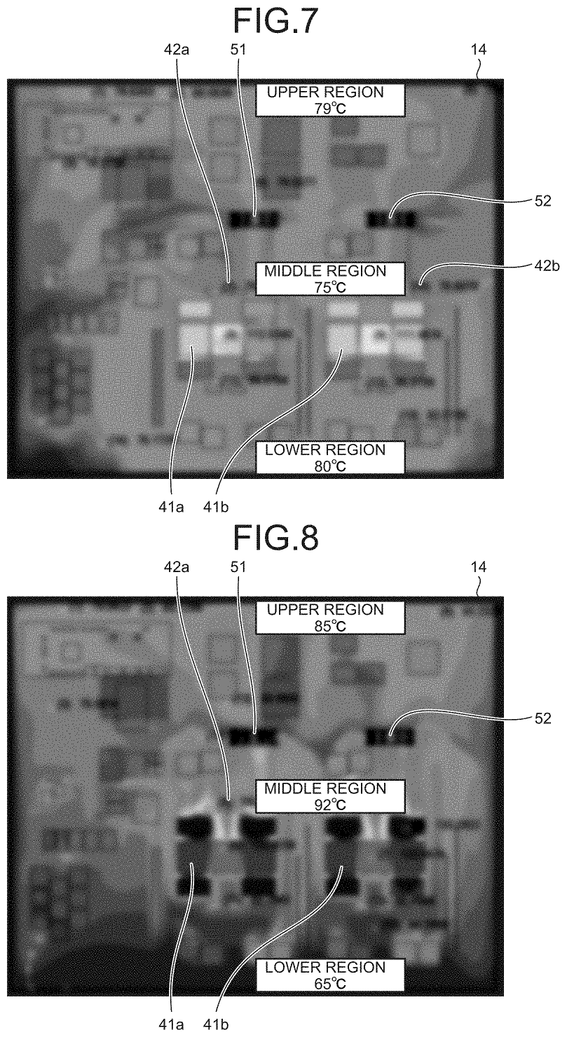

FIG. 7 is a diagram illustrating the analysis result of a thermal fluid analysis for estimating the temperature distribution inside the housing 14 of the charge/discharge device 1 illustrated in FIG. 3. In FIG. 7, the temperature distribution that appeared inside the housing 14 when the charge/discharge device 1 was operated while the first internal circulation fan 51 and the second internal circulation fan 52 were driven is represented by a contour figure. FIG. 8 is a diagram illustrating the analysis result of a thermal fluid analysis for estimating the temperature distribution inside the housing 14 of the charge/discharge device 1 illustrated in FIG. 3. In FIG. 8, the temperature distribution that appeared inside the housing 14 when the charge/discharge device 1 was operated while the first internal circulation fan 51 and the second internal circulation fan 52 were not driven is represented by a contour figure. Note that the front cover 23 is not illustrated in FIGS. 7 and 8.

As illustrated in FIG. 7, when the charge/discharge device 1 was operated while the first internal circulation fan 51 and the second internal circulation fan 52 were driven, the temperature of the upper region inside the housing 14 was 79° C., the temperature of the middle region inside the housing 14 was 75° C., and the temperature of the lower region inside the housing 14 was 80° C. Here, the temperature of the upper region is the temperature of the air around the upper end of the inner region of the housing 14. The temperature of the middle region is the temperature of the air around the vertical middle portion inside the housing 14. The temperature of the lower region is the temperature of the air around the lower end of the inner region of the housing 14.

On the other hand, as illustrated in FIG. 8, when the charge/discharge device 1 was operated while the first internal circulation fan 51 and the second internal circulation ran 52 were not driven, the temperature or the upper region was 85° C., the temperature of the middle region was 92° C., and the temperature of the lower region was 65° C. The reason why the temperatures of the upper region and the middle region were high and the temperature of the lower region was low is that hot air heated by the heat generated and radiated by the first reactors 41a and the second reactors 41b rose in the housing 14.

Comparing FIG. 7 and FIG. 8, the temperature of the upper region in FIG. 7 was 79° C. and lower than the temperature of the upper region in FIG. 8, namely 85° C., which can be considered as an effect of the first internal circulation fan 51 and the second internal circulation fan 52 as described above. Comparing FIG. 7 and FIG. 8, the temperature of the middle region in FIG. 7 was 75° C. and lower than the temperature of the middle region in FIG. 8, namely 92° C., which can also be considered as an effect of the first internal circulation fan 51 and the second internal circulation fan 52 as described above.

As illustrated in FIG. 6, the first capacitor 42a is placed near the first reactors 41a on the first substrate 31. As illustrated in FIG. 6, the second capacitor 42b is placed near the second reactors 41b on the second substrate 32. The first capacitor 42a and the second capacitor 42b are also relatively heat-sensitive components having a lower allowable temperature than reactors. For this reason, lowering the temperature of the middle region is important to ensure the lives of the first capacitor 42a and the second capacitor 42b.

Comparing FIG. 7 and FIG. 8, the temperature of the lower region in FIG. 7 was 80° C. and higher than the temperature of the lower region in FIG. 8, namely 65° C., which can also be considered as an effect of the first internal circulation fan 51 and the second internal circulation fan 52 driven for the operation or the charge/discharge device 1. That is, the reason why the temperature of the lower region increased from 65° C. to 80° C. can be considered that hot air heated by the heat radiation from the first reactors 41a and hot air heated by the heat radiation from the second reactors 41b were prevented from rising in the housing 14.

As described above, in the charge/discharge device 1 according to the first embodiment, air is blown from the first internal circulation fan 51 placed above the first reactors 41a that generates a large amount of heat downward to the first reactors 41a. Air is also blown from the second internal circulation fan 52 placed above the second reactors 41b that generates a large amount of heat downward to the second reactors 41b. Consequently, hot air heated by exhaust heat from the first reactors 41a and the second reactors 41b can be prevented from rising in the housing 14, and the air temperature difference in the vertical direction can be reduced inside the housing 14.

That is, the charge/discharge device 1 can suppress the increase of the ambient temperature of the upper region and the middle region in the housing 14, and can suppress the increase of the temperature of the air around the components placed in the upper region and the middle region of the housing 14. Therefore, even though temperature-sensitive components such as relays and capacitors are placed in the upper region and the middle region in the housing 14, the lives of the components can be ensured.

In other words, in the charge/discharge device 1, components that generate a large amount of heat during operation, such as reactors, are placed in the lower region in the housing 14, and internal circulation fans are placed in the middle region in the housing 14, so that air is blown from the internal circulation fans in the middle region to the components that generate a large amount of heat during operation in the lower region. Consequently, the charge/discharge device 1 can prevent exhaust heat from the components that generate a large amount of heat from rising in the housing 14, and can reduce the air temperature difference in the vertical direction inside the housing 14. Therefore, in the charge/discharge device 1, even though components having a lower allowable temperature than reactors are placed in the upper region and the middle region in the housing 14, the lives of the components are not shortened, and the degree of freedom in the arrangement of components inside the housing 14 is increased.

### Second Embodiment

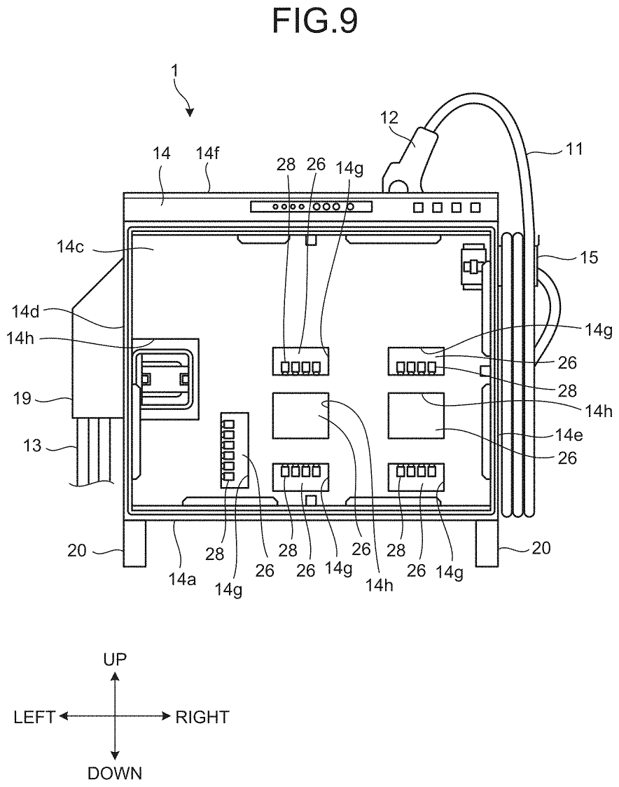

FIG. 9 is a front view illustrating the charge/discharge device 1 illustrated in FIG. 3, in which the front cover 23 is removed and all the substrates are omitted. A plurality of rectangular cut holes 14g are formed in the housing back surface 14c as viewed from the front. Parts of the heat sink 26 are exposed on the housing back surface 14c through the cut holes 14g. On the parts of the heat sink 26 exposed through the cut holes 14g, the switching elements 28 which are heat-generating elements are directly placed. The switching elements 28 are placed inside the housing 14. A plurality of cut holes 14h are formed in some parts of the housing back surface 14c where no switching elements 28 are placed.

The switching elements 28 are semiconductor elements such as insulated gate bipolar transistors (IGBTs), for example. A typical switching element has a lower allowable temperature than a reactor, but is likely to dissipate more heat than a reactor since it is a semiconductor element.

In the second embodiment, five cut holes 14g are formed. Four or six switching elements 28 are placed in the position corresponding to one cut hole 14g.

In FIG. 9, the switching elements 28 are placed between the first reactors 41a and the first internal circulation fan 51 and between the second reactors 41b and the second internal circulation fan 52, or below the first reactors 41a and the second reactors 41b. That is, a semiconductor element including a switching element, which is a third component, is placed between the first component and an internal circulation fan or below the first component.

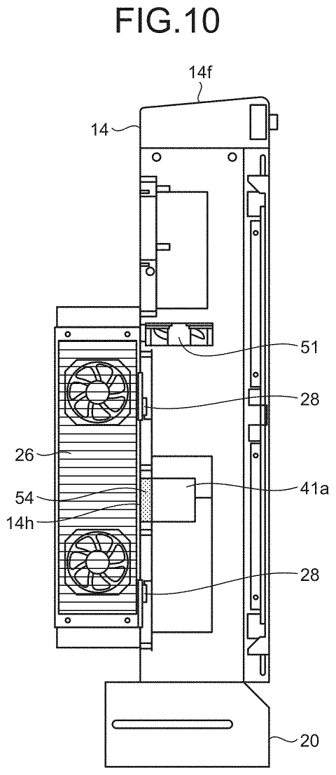

FIG. 10 is a cross-sectional view of the charge/discharge device 1 illustrated in FIG. 3. FIG. 10 depicts a longitudinal section passing through the middle of the first internal circulation fan 51 in the horizontal direction. A heat dissipation sheet 54 is placed directly below the first substrate 31 on which the first reactors 41a are mounted. The heat dissipation sheet 54 is placed in the position corresponding to the cut hole 14h in the housing 14. The heat dissipation sheet 54 is placed in direct contact with the heat sink 26. As a result, heat generated by the first reactors 41a can be efficiently transmitted to the heat sink 26 and radiated by the heat sink 26, so that the increase of the ambient temperature inside the housing 14 can be suppressed.

That is, the first substrate 31, which is the substrate on which the first component is mounted, is thermally connected to the heat sink 26, so that the heat dissipation of the first reactors 41a is enhanced, and the increase of the temperature inside the housing 14 is mitigated. Consequently, the life of the switching element placed between the first component and the internal circulation fan or below the first component can be extended. Therefore, according to the second embodiment, the life of the third component including the switching element placed in the middle region and the lower region in the housing 14 can be ensured, whereby the degree of freedom in the arrangement of components inside the housing 14 is increased.

The configurations described in the above-mentioned embodiments indicate examples of the contents of the present invention. The techniques of the embodiments can be combined with each other and with another well-known technique, and some of the configurations can be omitted or changed in a range not departing from the gist of the present invention.

### REFERENCE SIGNS LIST

1 charge/discharge device; 1a DC/DC converter; 1b DC/AC converter; 1c connector; 2 electric car; 2a drive storage battery; 3 external storage battery; 4 solar panel; 5 system power source; 6 load; 7 house; 11 charge/discharge cable; 12 charge/discharge connector; 13 system cable; 14 housing; 14a housing bottom surface; 14b housing front surface; 14c housing back surface; 14d housing left side surface; 14e housing right side surface; 14f housing top surface; 14g, 14h cut hole; 15 charge/discharge cable holder; 16 charge/discharge connector holder; 17 charge/discharge cable outlet; 18 system cable outlet; 19 system cable cover; 20 leg; 21 display unit; 22 switch unit; 23 front cover; 24 duct; 24a intake port; 24b exhaust port; 24c duct side surface; 25 cover; 26 heat sink; 26a fin; 27 fan unit; 27a fan; 28 switching element; 31 first substrate; 32 second substrate; 33 third substrate; 34 fourth substrate; 35 filter substrate; 36a first standing substrate; 36b second standing substrate; 36c third standing substrate; 37 terminal block; 41a first reactor; 41b second reactor; 42a first capacitor; 42b second capacitor; 43 relay; 51 first internal circulation fan; second internal circulation fan; 53 arrow; 54 heat dissipation sheet; 100 charge/discharge system.

1-11. (canceled)

12. A charge/discharge device comprising:
a first component to be used for power conversion;
a second component to be used for power conversion, the second component generating a smaller amount of heat than the first component during operation, the second component having a lower allowable temperature than the first component;
a housing to house the first component and the second component;
an internal circulation fan placed above the first component to blow air to the first component and circulate air inside the housing; and
a wall that is a substrate to be used for power conversion, an in-plane direction of the wall being parallel with a blowing direction of the internal circulation fan, the wall limiting spread of air blown from the internal circulation fan to the first component, wherein
the first component is mounted on a substrate and placed below the second component.

13. The charge/discharge device according to claim 12, comprising
a plurality of substrates on which the first component is mounted, wherein
the internal circulation fan is placed for each of the plurality of substrates.

14. The charge/discharge device according to claim 12, wherein
a plurality of substrates on which the first component is mounted are placed in parallel on a same plane, with their in-plane directions parallel with each other, and
the wall is placed between the plurality of substrates.

15. A charge/discharge device comprising:
a first component to be used for power conversion;
a second component to be used for power conversion, the second component generating a smaller amount of heat than the first component during operation, the second component having a lower allowable temperature than the first component;
a housing to house the first component and the second component; and
an internal circulation fan to circulate air inside the housing, wherein
the first component is a reactor to be used for power conversion and placed below the second component, and
the internal circulation fan is placed above the first component and blows air to the first component.

16. The charge/discharge device according to claim 15, wherein
the first component is mounted on a substrate.

17. The charge/discharge device according to claim 16, comprising
a plurality of substrates on which the first component is mounted, wherein
the internal circulation fan is placed for each of the plurality of substrates.

18. The charge/discharge device according to claim 16, comprising
a wall whose in-plane direction is parallel with a blowing direction of the internal circulation fan, the wall limiting spread of air blown from the internal circulation fan to the first component.

19. The charge/discharge device according to claim 18, wherein
the wall is a substrate to be used for power conversion.

20. The charge/discharge device according to claim 19, wherein
a plurality of substrates on which the first component is mounted are placed in parallel on a same plane, with their in-plane directions parallel with each other, and
the wall is placed between the plurality of substrates.

21. A charge/discharge device comprising:
a first component to be used for power conversion;
a second component to be used for power conversion, the second component generating a smaller amount of heat than the first component during operation, the second component having a lower allowable temperature than the first component;
a housing to house the first component and the second component; and
an internal circulation fan to circulate air inside the housing, wherein
the first component is placed below the second component,
the internal circulation fan is placed above the first component and blows air to the first component, and
the second component is an electronic component mounted on a filter substrate having a function of removing a noise component included in an input DC voltage.

22. The charge discharge device according to claim 21, wherein
the first component is mounted on a substrate.

23. The charge/discharge device according to claim 22, comprising
a plurality of substrates on which the first component is mounted, wherein
the internal circulation fan is placed for each of the plurality of substrates.

24. The charge/discharge device according to claim 22, comprising
a wall whose in-plane direction is parallel with a blowing direction of the internal circulation fan, the wall limiting spread of air blown from the internal circulation fan to the first component.

25. The charge/discharge device according to claim 24, wherein
the wall is a substrate to be used for power conversion.

26. The charge/discharge device according to claim 25, wherein
a plurality of substrates on which the first component is mounted are placed in parallel on a same plane, with their in-plane directions parallel with each other, and
the wall is placed between the plurality of substrates.

27. The charge/discharge device according to claim 21, wherein
the first component is a reactor to be used for power conversion.

28. A charge/discharge device comprising:
a first component to be used for power conversion;
a second component to be used for power conversion, the second component generating a smaller amount of heat than the first component during operation, the second component having a lower allowable temperature than the first component
a housing to house the first component and the second component;
an internal circulation fan to circulate air inside the housing; and
a heat sink placed on a back surface of the housing, wherein
the first component is mounted on a substrate and placed below the second component,
the internal circulation fan is placed above the first component and blows air to the first component,
the substrate on which the first component is mounted is thermally connected to the heat sink, and
a third component that is a semiconductor element including a switching element is placed between the first component and the internal circulation fan or below the first component.
